(19) United States
(12) Patent Application Publication
(10) Pub. No.: US 2025/0217299 A1
(43) Pub. Date: Jul. 3, 2025

(54) SEQUENTIAL-HYBRID ACCUMULATOR FLOOR PLAN FOR COMPUTE-IN-MEMORY

(71) Applicant: Taiwan Semiconductor Manufacturing Company, Ltd., Hsinchu (TW)

(72) Inventors: Je-Min Hung, Hsinchu City (TW); Brian Crafton, Hsinchu City (TW); Haruki Mori, Hsinchu City (TW); Hidehiro Fujiwara, Hsinchu City (TW)

(73) Assignee: Taiwan Semiconductor Manufacturing Company, Ltd., Hsinchu (TW)

(21) Appl. No.: 18/642,315

(22) Filed: Apr. 22, 2024

Related U.S. Application Data
(60) Provisional application No. 63/616,925, filed on Jan. 2, 2024.

(51) Int. Cl. G06F 12/0895

(52) U.S. Cl. CPC G06F 12/0895; G06F 2212/251

(57) ABSTRACT

A memory device may comprise a memory array, a first computing unit, and a second computing unit. The memory array may comprise a plurality of memory cells to store weights for a neural network. The first computing unit can be configured to receive the stored weights from the plurality of memory cells, and to generate a first partial sum according to the stored weights. The second computing unit can be configured to receive the stored weights from the plurality of memory cells and the first partial sum, and to generate a second partial sum according to the stored weights and the first partial sum. The second computing unit can be sequentially coupled to the first computing unit.

### CROSS-REFERENCE TO RELATED APPLICATION

This application claims priority to and the benefit of U.S. Provisional Application No. 63/616,925, filed Jan. 2, 2024, entitled “SYSTEM AND METHOD FOR FLOOR PLAN FOR COMPUTE-IN-MEMORY,” which is incorporated herein by reference in its entirety for all purposes.

### BACKGROUND

Memory devices are integral components of electronic systems, storing data in a manner that allows for rapid access and modification. Traditionally, memory devices have been designed to store binary information in the form of “0”s and “1”s across a vast array of memory cells. These cells, due to manufacturing variances and design constraints, often exhibit unbalanced physical structures, leading to disparities in their electrical characteristics. Compute-in-memory (CIM) technology integrates processing capabilities directly within memory arrays, enabling faster data computation by reducing the distance data must travel between storage and processing units.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a block diagram of a memory device 100, in accordance with some embodiments of the present disclosure.

FIG. 2 illustrates a detailed schematic diagram of the memory device 100 of FIG. 1, in accordance with some embodiments of the present disclosure.

FIG. 3 illustrates a detailed schematic diagram of the memory device 100 of FIG. 1, in accordance with some embodiments of the present disclosure.

FIG. 4 illustrates a detailed schematic diagram of the memory device 100 of FIG. 2, in accordance with some embodiments of the present disclosure.

FIG. 5 illustrates a detailed schematic diagram of the memory device 100 of FIG. 3, in accordance with some embodiments of the present disclosure.

FIG. 6 is a flowchart of an example method for fabricating the memory device 100 of FIG. 1, in accordance with some embodiments of the present disclosure.

FIG. 7 is a flowchart of an example method for fabricating the memory device 100, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the traditional floor plan of a compute-in-memory (CIM) macro, the design layout often presents significant challenges for routing accumulators (e.g., both global and local accumulators). This layout typically leads to severe routing congestion, as the paths for electrical connections between various components become overly complex and intertwined. The congestion not only hinders signal integrity and can potentially increase cross-talk among the circuits but also results in the inefficient use of metal layers. Such inefficiency escalates the need for higher numbers of metal layers or more complex metal stack configurations to accommodate the dense routing requirements. This not only complicates the manufacturing process but also increases production costs and can negatively impact the overall performance and scalability of the CIM system. Therefore, optimizing the floor plan to alleviate routing congestion and reduce metal layer usage is a crucial design consideration for improving CIM architectures.

To enhance the design of compute-in-memory (CIM) circuits, it's crucial to address the challenge of routing congestion which can be mitigated by adopting a more streamlined floor plan that promotes efficient routability. By reorganizing the layout, pathways for signal transmission can be simplified, reducing the complexity and overlap of routes that contribute to congestion. Furthermore, such optimization efforts aim to reduce the reliance on multiple metal layers for local and global routing, thereby not only simplifying the manufacturing process but also potentially reducing the physical thickness and fabrication cost of the chip. A careful balance between circuit density and routing simplicity can lead to more scalable and cost-effective CIM designs, with a significant suppression in the number of metal layers required. The present disclosure not only alleviates routing congestion but also enhances the overall performance and reliability of the CIM architecture.

Routability in the context of integrated circuit (IC) design refers to the ease with which electrical connections can be successfully and efficiently made between various components on a chip during the layout phase. It can be a measure of how readily and effectively the metal wires (also known as “routes”) can be placed within the layers of an IC without causing signal integrity issues, manufacturing problems, or violating design rules. For example, a design with high routability means that there is sufficient space for all necessary connections, with minimal risk of creating shorts, crosstalk, or other issues that can arise when routes are too dense or poorly organized. Factors that influence routability include the number of tracks within one metal layer, the complexity of the circuit, the number of layers available for routing, the precision of the manufacturing process, and the effectiveness of the design tools used to create the layout. Improving routability is essential for ensuring that a semiconductor chip can be manufactured reliably at scale, and for optimizing its performance and power efficiency. This is particularly important as memory circuits become more complex and denser with the ongoing advancements in semiconductor technology.

In a standard floor plan for a compute-in-memory (CIM) macro, local accumulators are strategically placed between CIM banks to facilitate multiply-accumulate (MAC) operations, which are fundamental to the macro's computational tasks. Despite the logic in positioning, these local accumulators operate by performing parallel accumulations, which can lead to a significant challenge: routing congestion. This congestion occurs because multiple parallel signals need to converge on the local accumulator, leading to a dense and complex web of interconnects. As a result, a higher count of metal layers is often required to accommodate all the necessary routing paths. For example, the design can demand up to 84 tracks for some routes and 70 tracks for others, illustrating the extensive metal layer usage that is needed to maintain signal integrity and functionality in these dense routing environments. This not only increases the complexity of the chip design but also impacts the manufacturing process, potentially leading to higher costs and scalability issues.

The present disclosure provides various embodiments of a memory device that address such issues (e.g., routability). For example, the memory device, as disclosed herein, includes a memory array, a first computing unit, and a second computing unit. The second computing unit is sequentially coupled to the first computing unit. In some embodiments, using a fully sequential floor plan can optimize overall routing tracks to 36 tracks and is able to use less metal layers. In some embodiments, using hybrid (e.g., partial sequential and partial parallel floor plan) floor plan can suppress overall routing tracks to 52 tracks and is able to use less metal layers.

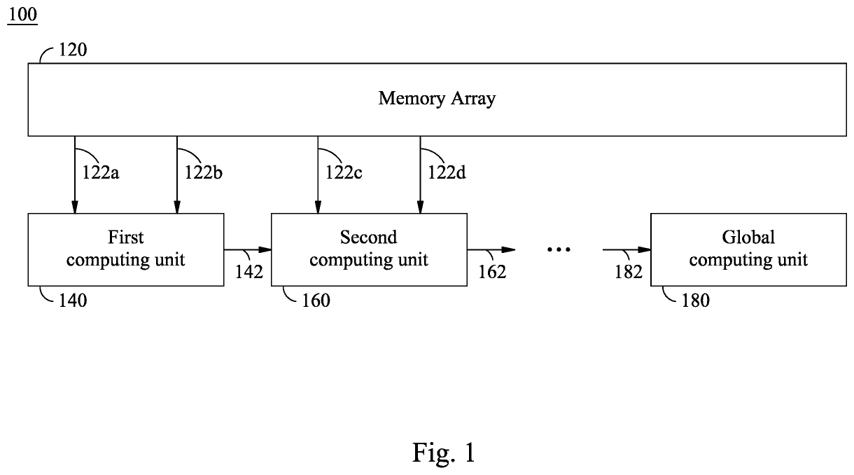

FIG. 1 illustrates a block diagram of a memory device 100, in accordance with some embodiments of the present disclosure. The memory device 100 may include a memory array 120, a first computing unit 140, and a second computing unit 160. In some embodiments, the memory device 100 may include a memory array 120, a first computing unit 140, a second computing unit 160, and a global computing unit 180.

The memory array 120 may comprise a plurality of memory cells. The plurality of memory cells can store weights for a neural network. One or more peripheral circuits (not shown) may be located at one or more regions peripheral to, or within, the memory array 120. The memory cells and the periphery circuits may be coupled by word lines and/or complementary bit lines BL and BLB, and data can read from and written to the memory bit cells via the complementary bit lines BL and BLB. Different voltage combinations applied to the word lines and bit lines may define a read, erase or write (program) operation on the memory bit cells. In some embodiments, the memory array 120 architecture can incorporate various types of non-volatile or volatile memory technologies, including but not limited to static random-access memory (SRAM), resistive random-access memory (ReRAM), magnetoresistive random-access memory (MRAM), and phase-change random access memory (PCRAM).

Deep learning utilizes neural networks to achieve artificial intelligence. These networks comprise numerous processing nodes that are interlinked, facilitating machine learning through the analysis of example data. Take, for instance, a system designed to recognize objects: it might process thousands of object images, such as trucks, to discern and learn the visual patterns that correspond to the object in new images. The structure of neural networks is typically in layers, and data flows through these layers in a single, forward direction. Each node within the network may have connections to multiple nodes in the subsequent layer to which it sends data, as well as to numerous nodes in the preceding layer from which it receives data.

Within the neural network, a node attributes a numerical value, termed a “weight,” to its connections. When activated, a node can multiply incoming data by this weight and sum up the products from all its connections, resulting in a single numeric output. If the output falls below a certain threshold, the node can withhold it from progressing to the next layer. Conversely, if the output surpasses the threshold, the node can transmit this sum to the nodes it is connected to in the following layer. In a deep learning system, a neural network model is stored in memory and computational logic in a processor performs multiply-accumulate (MAC) computations on the parameters (e.g., weights) stored in the memory. In some embodiments, the weights can be stored in the plurality of memory cells within the memory array 120.

In some embodiments, the first computing unit 140 can be configured to receive multiple inputs 122a, 122b from the plurality of memory cells 120. The multiple inputs 122a, 122b may include at least one of: the stored weights from the plurality of memory cells 120 or an input activation vector element. In some embodiments, the first computing unit 140 can be at least one of: a local accumulator, a full adder, a half adder, a summation register, a partial sum register, or an accumulation circuit. In some embodiments, weights (W) or input activation vector elements can be stored in a sub-array of the memory array 120. Each output of the sub-array can be an input to a computing unit 140. For example, the first computing unit 140 can be configured to receive the stored weights from the plurality of memory cells 120. In some embodiments, the first computing unit 140 is inserted between sub-arrays of memory cells 120. The first computing unit 140 and the sub-arrays can be connected on a plurality of local bit lines. In certain embodiments, at least one additional computing unit can be inserted between the memory array 120 and the first computing unit 140. In some embodiments, the first computing unit 140 can be configured to generate a first partial sum 142 according to the stored weights 122a, 122b. In certain embodiments, the first computing unit 140 can be configured to generate a first partial sum 142 according to the stored weights and a partial sum from the at least one additional computing unit.

In some embodiments, the second computing unit 160 can be configured to receive multiple inputs 122c, 122d from the plurality of memory cells 120. The second computing unit 160 can be configured to receive the first partial sum 142 from the first computing unit 140. The multiple inputs 122c, 122d may include at least one of: the stored weights from the plurality of memory cells 120 or an input activation vector element. In some embodiments, the second computing unit 160 can be at least one of: a local accumulator, a full adder, a half adder, a summation register, a partial sum register, or an accumulation circuit. In some embodiments, weights (W) or input activation vector elements can be stored in a sub-array of the memory array 120. Each output of the sub-array can be an input to a computing unit 160. For example, the second computing unit 160 can be configured to receive the stored weights from the plurality of memory cells 120. In some embodiments, the second computing unit 160 is inserted between sub-arrays of memory cells 120. The second computing unit 160 and the sub-arrays can be connected on a plurality of local bit lines. In certain embodiments, at least one additional computing unit can be inserted between the memory array 120 and the second computing unit 160. In some embodiments, the second computing unit 160 can be configured to generate a second partial sum 162 according to the stored weights 122c, 122d and the first partial sum 142. In certain embodiments, the second computing unit 160 can be configured to generate a second partial sum 162 according to the stored weights, the first partial sum 142, and a partial sum from the at least one additional computing unit.

In some embodiments, the first computing unit 140 may generate the first partial sum 142 by multiplying an input activation vector element with the stored weights within a sub-array of memory cells 120. The second computing unit 160 may generate the second partial sum 162 by multiplying an input activation vector element with the stored weights within a sub-array of memory cells 120. In some embodiments, each of the plurality of memory cells 120 may include a plurality of word lines. Multiplication of an input activation vector element on one of the plurality of word lines with a weight stored in the plurality of memory cells can be computed through access to a sub-array of memory cells via the plurality of word lines.

In some embodiments, the second computing unit 160 can be sequentially coupled to the first computing unit 140. In some embodiments, the first computing unit 140 and the second computing unit 160 can be sequentially coupled in a same metallization/metal layer. In some embodiments, the first computing unit 140 can be directly interconnected to the second computing unit 160.

In some embodiments, a memory device 100 may adopt a fully sequential floor plan. By adopting the fully sequential floor plan in the design of memory devices can lead to a more optimal use of routing tracks. By arranging the components in a sequential manner, the total number of routing tracks required can be significantly reduced. This streamlined approach facilitates a more organized and less congested routing scheme, thereby allowing for the use of fewer metal layers within the circuit. Additionally, with fewer layers, the electrical path lengths are shortened, which can enhance the signal integrity and potentially improve the operational speed of the circuit.

In some embodiments, a memory device 100 may implement a hybrid floor plan (e.g., partial sequential floor plan and partial parallel floor plan). By implementing a hybrid floor plan that combines both sequential and parallel elements in integrated circuit design can provide a substantial improvement in terms of routability and layer usage. By selectively employing sequential routing where feasible and parallel routing where necessary, the total number of routing tracks can be effectively reduced. This balanced approach mitigates the routing congestion typically associated with parallel designs while still maintaining the design compactness that purely sequential floor plans may compromise. The result is a layout that requires fewer metal layers, which can significantly lower the complexity and cost of manufacturing. This hybrid floor plan thus offers an efficient way to optimize the routing infrastructure of the chip, contributing to a more streamlined manufacturing process and improved overall circuit performance.

In some embodiments, the global computing unit 180 can be configured to accumulate at least one partial sum 182 (e.g., first partial sum 142, and/or second partial sum 162) of multiplications from the first computing unit 140 and the second computing unit 160. In some embodiments, the global computing unit 180 can be at least one of: a global accumulator, a full adder, a half adder, a summation register, a partial sum register, or an accumulation circuit. In some embodiments, at least one additional computing unit can be inserted between the global computing unit 180 and the second computing unit 160. In certain embodiments, the global computing unit 180 can be sequentially coupled to the first computing unit 140, the second computing unit 160, and the at least one additional computing unit.

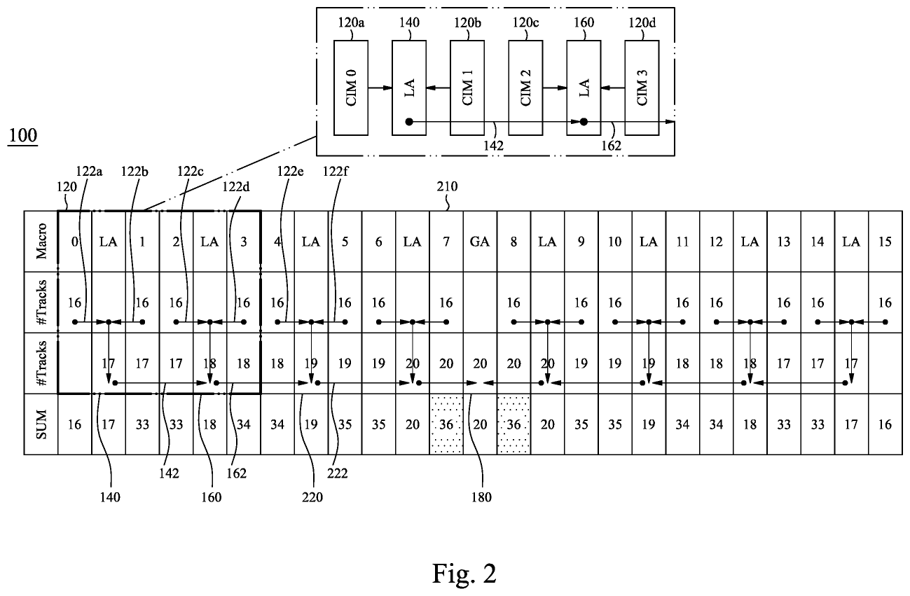

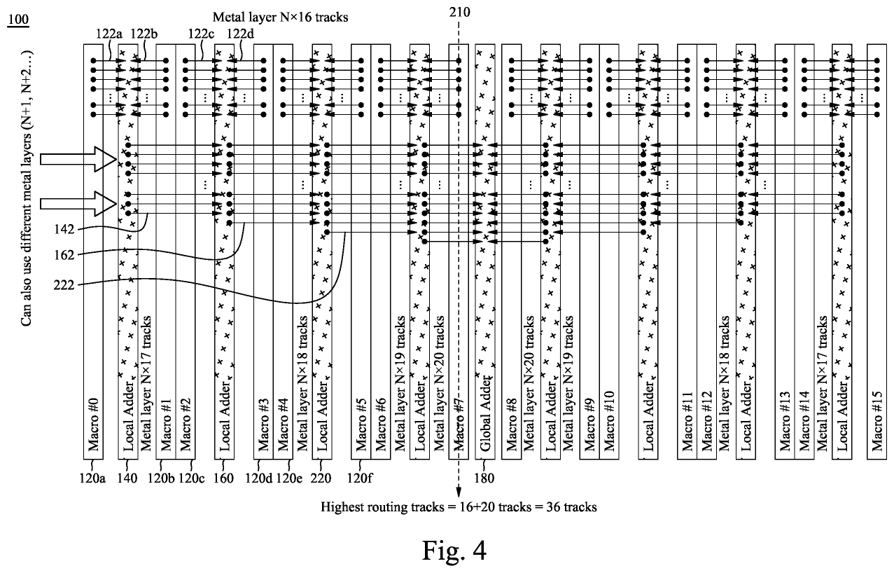

FIG. 2 illustrates a detailed schematic diagram of the memory device 100 of FIG. 1, in accordance with some embodiments of the present disclosure. FIG. 4 illustrates a detailed schematic diagram of the memory device 100 of FIG. 2, in accordance with some embodiments of the present disclosure. The memory device 100 may include a memory array 120, a first computing unit 140, a second computing unit 160, and a third computing unit 220. In some embodiments, the memory device 100 may include a memory array 120, a first computing unit 140, a second computing unit 160, a third computing unit 220, and a global computing unit 180. The memory devices 100 of FIGS. 2 and 4 are substantially similar to the memory device 100 of FIG. 1. The specific operations of similar elements, which are already discussed in detail in above paragraphs, are omitted herein for the sake of brevity, unless there is a need to introduce the co-operation relationship with the elements shown in FIGS. 2 and 4. In FIGS. 2 and 4, suppose there are 16 partial sums to be accumulated from 16 CIM banks, with each partial sum being 16 bits.

In some embodiments, the third computing unit 220 can be configured to receive multiple inputs 122e, 122f from the plurality of memory cells 120. The third computing unit 220 can be configured to receive the second partial sum 162 from the second computing unit 160. The multiple inputs 122e, 122f may include at least one of: the stored weights from the plurality of memory cells 120 or an input activation vector element. In some embodiments, the third computing unit 220 can be at least one of: a local accumulator, a full adder, a half adder, a summation register, a partial sum register, or an accumulation circuit. In some embodiments, weights (W) or input activation vector elements can be stored in a sub-array of the memory array 120. Each output of the sub-array can be an input to a computing unit 220. For example, the third computing unit 220 can be configured to receive the stored weights from the plurality of memory cells 120. In some embodiments, the third computing unit 220 is inserted between sub-arrays of memory cells 120. The third computing unit 220 and the sub-arrays can be connected on a plurality of local bit lines. In certain embodiments, at least one additional computing unit can be inserted between the memory array 120 and the third computing unit 220. In some embodiments, the third computing unit 220 can be configured to generate a third partial sum 222 according to the stored weights 122e, 122f and the second partial sum 162. In certain embodiments, the third computing unit 220 can be configured to generate a third partial sum 222 according to the stored weights, the second partial sum 162, and a partial sum from the at least one additional computing unit.

In some embodiments, the third computing unit 220 can be sequentially coupled to the first computing unit 140 and the second computing unit 160. In some embodiments, the third computing unit 220, the first computing unit 140, and the second computing unit 160 can be sequentially coupled in the same metallization/metal layer. In some embodiments, the third computing unit 220 can be directly interconnected to the second computing unit 160. In some embodiments, a memory device 100 may adopt a fully sequential floor plan (e.g., 140, 160, and 220). By adopting the fully sequential floor plan in the design of memory devices can lead to a more optimal use of routing tracks. By arranging the components in a sequential manner, the total number of routing tracks required can be significantly reduced (e.g., 36 routing tracks). This streamlined approach facilitates a more organized and less congested routing scheme, thereby allowing for the use of fewer metal layers within the circuit. Additionally, with fewer layers, the electrical path lengths are shortened, which can enhance the signal integrity and potentially improve the operational speed of the circuit.

As illustrated in FIGS. 2 and 4, a first memory cell 120a (e.g., CIM 0) can utilize 16 routing tracks to transmit/convey neural network data to the first local accumulator 140. A second memory cell 120b (e.g., CIM 1) can utilize 16 routing tracks to transmit/convey neural network data to the first local accumulator 140. The first local accumulator 140 may receive/compile the neural network data from the first memory cell 120a and the second memory cell 120b. The first local accumulator 140 may generate a first partial sum 142 and transmit the first partial sum 142 to the second local accumulator 160 by using 17 routing tracks. A third memory cell 120c (e.g., CIM 2) can utilize 16 routing tracks to transmit/convey neural network data to the second local accumulator 160. A fourth memory cell 120d (e.g., CIM 3) can utilize 16 routing tracks to transmit/convey neural network data to the second local accumulator 160. The second local accumulator 160 may receive the neural network data from the third memory cell 120c and the fourth memory cell 120d. The second local accumulator 160 may generate a second partial sum 162. The second local accumulator 160 may transmit the second partial sum 162 to a subsequent component (e.g., a third local accumulator 200) by using 18 routing tracks. The third local accumulator 220 may receive the neural network data from the memory cells. The third local accumulator 220 may generate a third partial sum 222. The third local accumulator 220 may transmit the third partial sum 222 to a following element by using 19 routing tracks. In such case, the number of highest routing tracks in this system is 36 routing tracks, for CIM 7 210. Compared to the conventional routing floor plan design, which uses up to 84 routing tracks, the present disclosure provides a memory device that reduces routing congestion and minimizes the usage of metal layers.

In some embodiments, the first computing unit 140 can be sequentially coupled to the second computing unit 160 by using the routing tracks within the same metallization layer (e.g., metal layer N). In some embodiments, multiple metal layers can be utilized (e.g., metal layer N+1, N+2). The first memory cell 120a and the second memory cell 120b can be in the same metal layer. The first memory cell 120a and the first computing unit 140 can be in different metallization layers. For example, the first memory cell 120a and the second memory cell 120b can be formed in metal layer N. The first computing unit 140, the second computing unit 160, the third computing unit 222 can be formed in metal layer N+1.

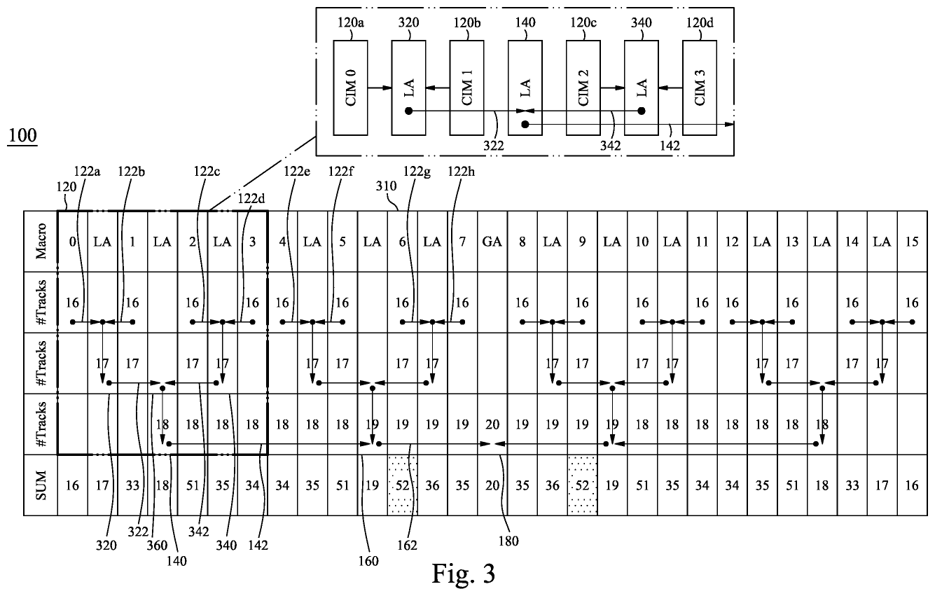

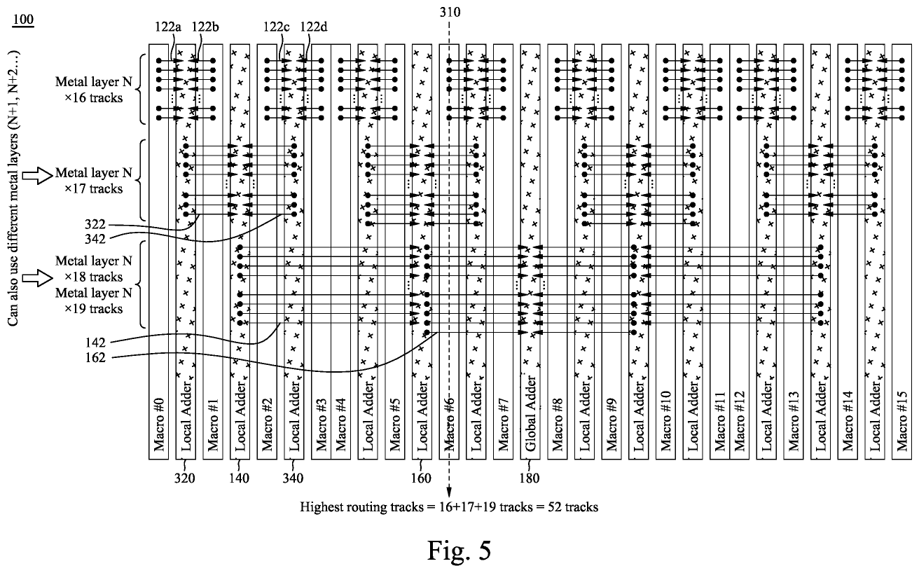

FIG. 3 illustrates a detailed schematic diagram of the memory device 100 of FIG. 1, in accordance with some embodiments of the present disclosure. FIG. 5 illustrates a detailed schematic diagram of the memory device 100 of FIG. 3, in accordance with some embodiments of the present disclosure. The memory device 100 may include a memory array 120, a first computing unit 140, a second computing unit 160, a fourth computing unit 320, and a fifth computing unit 340. In some embodiments, the memory device 100 may include a memory array 120, a first computing unit 140, a second computing unit 160, a fourth computing unit 320, a fifth computing unit 340, and a global computing unit 180. The memory devices 100 of FIGS. 3 and 5 are substantially similar to the memory device 100 of FIG. 1. The specific operations of similar elements, which are already discussed in detail in above paragraphs, are omitted herein for the sake of brevity, unless there is a need to introduce the co-operation relationship with the elements shown in FIGS. 3 and 5. In FIGS. 3 and 5, suppose there are 16 partial sums to be accumulated from 16 CIM banks, with each partial sum being 16 bits.

In some embodiments, the fourth computing unit 320 can be configured to receive multiple inputs 122a, 122b from the plurality of memory cells 120. The multiple inputs 122a, 122b may include at least one of: the stored weights from the plurality of memory cells 120 or an input activation vector element. In some embodiments, the fourth computing unit 320 can be at least one of: a local accumulator, a full adder, a half adder, a summation register, a partial sum register, or an accumulation circuit. In some embodiments, weights (W) or input activation vector elements can be stored in a sub-array of the memory array 120. Each output of the sub-array can be an input to a computing unit 320. For example, the fourth computing unit 320 can be configured to receive the stored weights from the plurality of memory cells 120. In some embodiments, the fourth computing unit 320 is inserted between sub-arrays of memory cells 120. The fourth computing unit 320 and the sub-arrays can be connected on a plurality of local bit lines. In certain embodiments, at least one additional computing unit can be inserted between the memory array 120 and the fourth computing unit 320. In some embodiments, the fourth computing unit 320 can be configured to generate a fourth partial sum 322 according to the stored weights 122a, 122b. In certain embodiments, the fourth computing unit 320 can be configured to generate a fourth partial sum 322 according to the stored weights and a partial sum from the at least one additional computing unit.

In some embodiments, the fifth computing unit 340 can be configured to receive multiple inputs 122c, 122d from the plurality of memory cells 120. The multiple inputs 122c, 122d may include at least one of: the stored weights from the plurality of memory cells 120 or an input activation vector element. In some embodiments, the fifth computing unit 340 can be at least one of: a local accumulator, a full adder, a half adder, a summation register, a partial sum register, or an accumulation circuit. In some embodiments, weights (W) or input activation vector elements can be stored in a sub-array of the memory array 120. Each output of the sub-array can be an input to a computing unit 340. For example, the fifth computing unit 340 can be configured to receive the stored weights from the plurality of memory cells 120. In some embodiments, the fifth computing unit 340 is inserted between sub-arrays of memory cells 120. The fifth computing unit 340 and the sub-arrays can be connected on a plurality of local bit lines. In certain embodiments, at least one additional computing unit can be inserted between the memory array 120 and the fifth computing unit 340. In some embodiments, the fifth computing unit 340 can be configured to generate a fifth partial sum 342 according to the stored weights 122c, 122d. In certain embodiments, the fifth computing unit 340 can be configured to generate a fifth partial sum 342 according to the stored weights and a partial sum from the at least one additional computing unit.

In some embodiments, the first computing unit 140 can be parallelly coupled to the fourth computing unit 320 and the fifth computing unit 340 to receive the fourth partial sum 322 and the fifth partial sum 342. The first computing unit 140 can receive the fourth partial sum 322 from the fourth computing unit 320 and the fifth partial sum 342 from the fifth computing unit 340. The first computing unit 140 can generate the first partial sum 142 according to the fourth partial sum 322 and the fifth partial sum 342. In some embodiments, the fourth computing unit 320 and the first computing unit 140 can be in different metallization/metal layers. The fourth computing unit 322 and the fifth computing unit 340 can be in a same metallization/metal layer. In some embodiments, the fourth computing unit 320 can be interconnected to the first computing unit 140 using a via structure 360. The fifth computing unit 340 can be interconnected to the first computing unit 140 via the via structure 360.

In some embodiments, the second computing unit 160 can be configured to receive multiple inputs 122e, 122f, 122g, 122h from the plurality of memory cells 120. The second computing unit 160 can be configured to receive the first partial sum 142 from the first computing unit 140. The multiple inputs 122e, 122f, 122g, 122h may include at least one of: the stored weights from the plurality of memory cells 120 or an input activation vector element. In some embodiments, the second computing unit 160 can be at least one of: a local accumulator, a full adder, a half adder, a summation register, a partial sum register, or an accumulation circuit. In some embodiments, weights (W) or input activation vector elements can be stored in a sub-array of the memory array 120. Each output of the sub-array can be an input to a computing unit 160. For example, the second computing unit 160 can be configured to receive the stored weights 122e, 122f, 122g, 122h from the plurality of memory cells 120. In some embodiments, the second computing unit 160 is inserted between sub-arrays of memory cells 120. The second computing unit 160 and the sub-arrays can be connected on a plurality of local bit lines. In certain embodiments, at least one additional computing unit can be inserted between the memory array 120 and the second computing unit 160. In some embodiments, the second computing unit 160 can be configured to generate a second partial sum 162 according to the stored weights 122e, 122f, 122g, 122h and the first partial sum 142. In certain embodiments, the second computing unit 160 can be configured to generate a second partial sum 162 according to the stored weights, the first partial sum 142, and a partial sum from the at least one additional computing unit.

In some embodiments, the second computing unit 160 can be sequentially coupled to the first computing unit 140. In some embodiments, the first computing unit 140 and the second computing unit 160 can be sequentially coupled within the same metallization/metal layer (e.g., metal layer N, N+1, or N+2). In some embodiments, the first computing unit 140 can be directly interconnected to the second computing unit 160.

In some embodiments, a memory device 100 may implement a hybrid floor plan (e.g., partial sequential floor plan and partial parallel floor plan). By implementing a hybrid floor plan that combines both sequential (e.g., the fourth computing unit 320, the fifth computing unit 340, and the first computing unit 140) and parallel (e.g., the first computing unit 140 and the second computing unit 160) elements in integrated circuit design can provide a substantial improvement in terms of routability and layer usage. By selectively employing sequential routing where feasible and parallel routing where necessary, the total number of routing tracks can be effectively reduced (e.g., 52 routing tracks). This balanced approach mitigates the routing congestion typically associated with parallel designs while still maintaining the design compactness that purely sequential floor plans may compromise. The result is a layout that requires fewer metal layers, which can significantly lower the complexity and cost of manufacturing. This hybrid floor plan thus offers an efficient way to optimize the routing infrastructure of the chip, contributing to a more streamlined manufacturing process and improved overall circuit performance.

As illustrated in FIGS. 3 and 5, a first memory cell 120a (e.g., CIM 0) can utilize 16 routing tracks to transmit/convey neural network data to the fourth local accumulator 320. A second memory cell 120b (e.g., CIM 1) can utilize 16 routing tracks to transmit/convey neural network data to the fourth local accumulator 320. The fourth local accumulator 320 may receive/compile the neural network data from the first memory cell 120a and the second memory cell 120b. The fourth local accumulator 320 may generate a fourth partial sum 322 and transmit the fourth partial sum 3222 to the first local accumulator 140 by using 17 routing tracks in a different metal layer. A third memory cell 120c (e.g., CIM 2) can utilize 16 routing tracks to transmit/convey neural network data to the fifth local accumulator 340. A fifth memory cell 120d (e.g., CIM 3) can utilize 16 routing tracks to transmit/convey neural network data to the fifth local accumulator 340. The fifth local accumulator 340 may receive the neural network data from the third memory cell 120c and the fourth memory cell 120d. The fifth local accumulator 340 may generate a fifth partial sum 342. The fifth local accumulator 342 may transmit the fifth partial sum 342 to the first computing unit 140 by using 17 routing tracks. The first local accumulator 140 may receive the neural network data from the memory cells 120. The first local accumulator 140 may generate a first partial sum 142 according to the fourth partial sum 322 and the fifth partial sum 342. The first local accumulator 140 may transmit the first partial sum 142 to a following element (e.g., the second computing unit 160) by using 18 routing tracks. The second local accumulator 160 may receive the first partial sum 142 and the neural network data from the memory cells. The second local accumulator 160 may generate a second partial sum 162. The second local accumulator 160 may transmit the second partial sum 162 to a subsequent component (e.g., a global accumulator 180) by using 19 routing tracks. In such case, the number of highest routing tracks in this system is 52 routing tracks, for CIM 6 310. Compared to the conventional routing floor plan design, which uses up to 84 routing tracks, the present disclosure provides a memory device that reduces routing congestion and minimizes the usage of metal layers.

In some embodiments, the first computing unit 140 can be parallelly coupled to the fourth computing unit 320 and the fifth computing unit 340 by using the routing tracks and a via structure 360. In some embodiments, the fourth computing unit 320 and the first computing unit 140 can be in different metallization layers (e.g., metal layer N, N+1, and N+2). The fourth computing unit 320 and the fifth computing unit 340 can be in the same metallization layer (e.g., metal layer N). In certain embodiments, the first computing unit 140, the fourth computing unit 320, and the fifth computing unit 340 can all be in the same metallization layer (e.g., metal layer N). In some embodiments, the first computing unit 140 can be sequentially coupled to the second computing unit 160 by using the routing tracks within the same metallization layer (e.g., metal layer N). In some embodiments, multiple metal layers can be utilized (e.g., metal layer N+1, N+2). The first memory cell 120a and the second memory cell 120b can be in the same metal layer. The first memory cell 120a and the fourth computing unit 320 (or the fifth computing unit 340) can be in different metallization layers. For example, the first memory cell 120a and the second memory cell 120b can be formed in metal layer N. The fourth computing unit 320 and the fifth computing unit 340 can be formed in metal layer N+1. The first computing unit 140 and the second computing unit 160 can be formed in metal layer N+2.

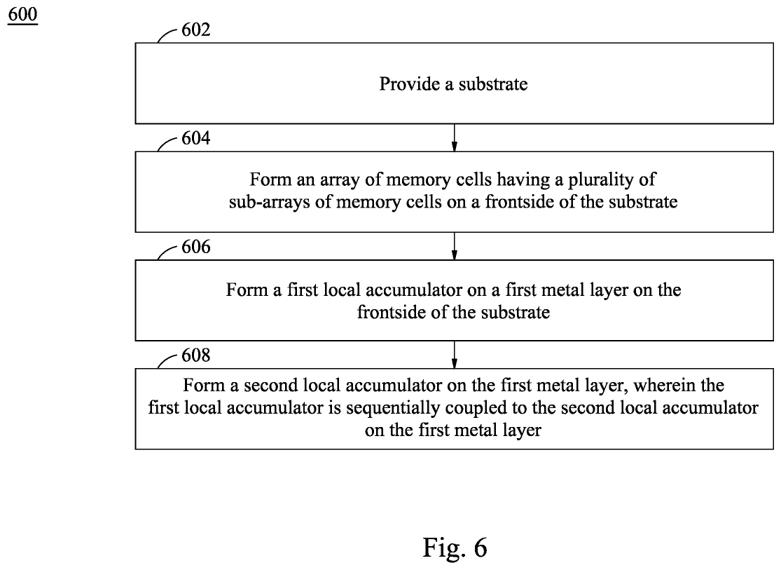

FIG. 6 is a flowchart of an example method 600 for fabricating the memory device 100 of FIG. 1, in accordance with some embodiments of the present disclosure. It is understood that FIG. 6 has been simplified for a better understanding of the concepts of the present disclosure. Accordingly, it should be noted that additional processes may be provided before, during, and after the method of FIG. 6, and that some other processes may only be briefly described herein.

Referring now to FIG. 6, operation 602 can providing a substrate. The substrate may have a frontside and a backside opposite to each other. The substrate may be a semiconductor substrate, such as a bulk semiconductor, a semiconductor-on-insulator (SOI) substrate, or the like, which may be doped (e.g., with a p-type or an n-type dopant) or undoped.

Next, the method 600 proceeds to operation 604 of forming an array of memory cells 120 having a plurality of sub-arrays of memory cells on the frontside of the substrate. Each sub-array of memory cells can be disposed next to each other sub-array of memory cells. In some embodiments, a sub-array of the memory array 120 may store weights (W) or input activation vector elements for a neural network. Each output of the sub-array can be an input to a computing unit.

Next, the method 600 proceeds to operation 606 of forming a first local accumulator 140 on a first metal layer on the frontside of the substrate. The first local accumulator 140 may generate a first partial sum 142 by multiplying an input activation vector element with the stored weights within a sub-array of memory cells 120.

Next, the method 600 proceeds to operation 608 of forming a second local accumulator 160 on the first metal layer. The first computing unit 140 can be at least one of: a local accumulator, a full adder, a half adder, a summation register, a partial sum register, or an accumulation circuit. The first local accumulator 140 can be sequentially coupled to the second local accumulator 160 on the first metal layer. The second computing unit 160 can be at least one of: a local accumulator, a full adder, a half adder, a summation register, a partial sum register, or an accumulation circuit. In some embodiments, the first computing unit 140 can be directly interconnected to the second computing unit 160. The second computing unit 160 can be configured to receive multiple inputs from the plurality of memory cells 120. The second computing unit 160 can be configured to receive the first partial sum 142 from the first computing unit 140. In some embodiments, the second computing unit 160 can be configured to generate a second partial sum according to the stored weights and the first partial sum.

Next, the method 600 may proceed to operation of forming a third local accumulator formed on the first metal layer. The third local accumulator can be sequentially coupled to the first local accumulator and the second local accumulator on the first metal layer. The third computing unit can be at least one of: a local accumulator, a full adder, a half adder, a summation register, a partial sum register, or an accumulation circuit. In some embodiments, the third computing unit can be sequentially coupled to the first computing unit 140 and the second computing unit 160. In some embodiments, the third computing unit can be parallelly coupled to the first computing unit 140.

In some embodiments, the method 600 may proceed to operation of forming an interconnect structure on the backside of the substrate. The interconnect structure can be coupled to the array of memory cells 120, the first local accumulator 140, and the second local accumulator 160 on the frontside of the substrate. There can be a plurality of first via structures vertically extending through the substrate from its backside to the frontside. In certain embodiments, the array of memory cells 120, the first local accumulator 140, and the second local accumulator 160 can be also formed on the backside of the substrate. The first local accumulator 140 can be sequentially coupled to the second local accumulator 160 within the interconnect structure.

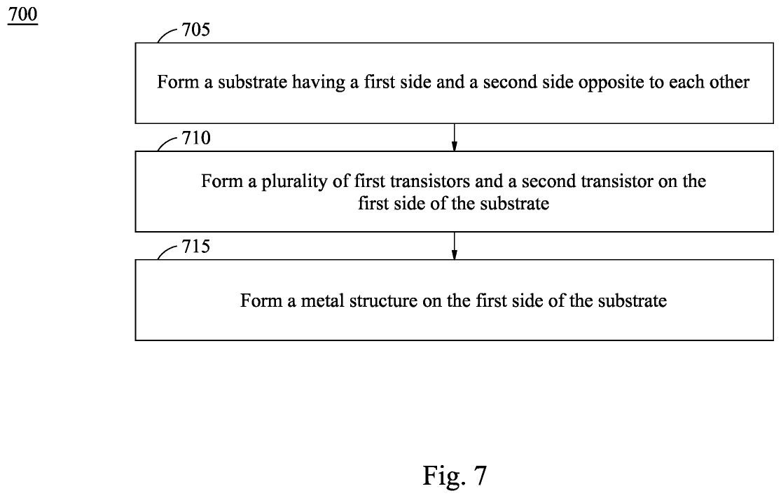

FIG. 7 is a flowchart of an example method 700 for fabricating the memory device 100, in accordance with some embodiments of the present disclosure. It is understood that FIG. 7 has been simplified for a better understanding of the concepts of the present disclosure. Accordingly, it should be noted that additional processes may be provided before, during, and after the method of FIG. 7, and that some other processes may only be briefly described herein.

Referring now to FIG. 7, operation 705 can provide a substrate. The substrate may have a first side and a second side opposite to each other. The substrate may be a semiconductor substrate, such as a bulk semiconductor, a semiconductor-on-insulator (SOI) substrate, or the like, which may be doped (e.g., with a p-type or an n-type dopant) or undoped.

Next, the method 700 proceeds to operation 710 of forming a plurality of first transistors and a second transistor on the first side of the substrate. The plurality of first transistors can be a hardware component that stores data. Each of the plurality of first transistors may have p-type conductivity or n-type conductivity. In one aspect, the plurality of first transistors can be embodied as a semiconductor memory device or an array of memory cells 120. In some embodiments, the second transistor can be for a header device on the first side of the substrate. The second transistor may have p-type conductivity or n-type conductivity.

Next, the method 700 proceeds to operation 715 of forming a metal structure (e.g., word lines and/or bit lines, interconnect) on the first side of the substrate. The plurality of first transistors and the metal structure (e.g., word lines and/or bit lines) can be for a plurality of memory cells 120 on the first side of the substrate. In some embodiments, a conductor structure can be formed on the first side of the substrate. The conductor structure can be configured to deliver the supply voltage to the first transistors. A plurality of via structures can be formed on the first side of the substrate. The via structures can be configured to electrically couple a source/drain terminal of the transistor to the conductor structure. In some embodiments, the first local accumulator 140 and the second local accumulator 160 can be also formed within the metal structure. The first local accumulator 140 can be sequentially coupled to the second local accumulator 160 within the interconnect structure.

In the present disclosure, accumulators in a compute-in-memory (CIM) circuit are strategically placed within a sequential floor plan/layout, enabling them to aggregate partial sums (PSUMs) effectively. This methodical arrangement serves to alleviate routing congestion by streamlining the paths that signals must traverse, thus reducing the complexity of the network. Furthermore, it curtails the dependency on multiple metal layers, contributing to a more straightforward, cost-effective manufacturing process, and potentially improving signal integrity due to shorter interconnect lengths.

The present disclosure also introduces a hybrid floor plan approach, merging both sequential and parallel layouts for accumulators collecting PSUMs. This design still aims to mitigate routing congestion by combining the benefits of a sequential system (reduced complexity and metal usage) with the higher connectivity of parallel configurations. This hybrid model offers a balanced solution that can adapt to varying design constraints and performance requirements, providing a versatile framework that can maintain signal integrity and reduce cross-talk, even in densely packed circuit architectures.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a memory array comprising a plurality of memory cells to store weights for a neural network;
a first computing unit configured to receive the stored weights from the plurality of memory cells, and to generate a first partial sum according to the stored weights; and
a second computing unit configured to receive the stored weights from the plurality of memory cells and the first partial sum, and to generate a second partial sum according to the stored weights and the first partial sum, wherein the second computing unit is sequentially coupled to the first computing unit.

2. The memory device of claim 1, wherein the first computing unit and the second computing unit are in a same metallization layer.

3. The memory device of claim 1, wherein the first computing unit is directly interconnected to the second computing unit.

4. The memory device of claim 1, comprising:
a third computing unit configured to receive the stored weights from the plurality of memory cells and the second partial sum, and to generate a third partial sum according to the stored weights and the second partial sum, wherein the third computing unit is sequentially coupled to the first computing unit and the second computing unit.

5. The memory device of claim 4, wherein the third computing unit and the first computing unit are in a same metallization layer.

6. The memory device of claim 1, comprising:
a fourth computing unit configured to receive the stored weights from the plurality of memory cells, and to generate a fourth partial sum according to the stored weights;
a fifth computing unit configured to receive the stored weights from the plurality of memory cells, and to generate a fifth partial sum according to the stored weights, wherein the first computing unit is parallelly coupled to the fourth computing unit and the fifth computing unit to receive the fourth partial sum and the fifth partial sum, and to generate the first partial sum.

7. The memory device of claim 6, wherein the fourth computing unit and the first computing unit are in different metallization layers, and the fourth computing unit and the fifth computing unit are in a same metallization layer.

8. The memory device of claim 6, wherein the fourth computing unit is interconnected to the first computing unit via a via structure, wherein the fifth computing unit is interconnected to the first computing unit via the via structure.

9. The memory device of claim 1, comprising:
a global computing unit configured to accumulate partial sums of multiplications from the first computing unit and the second computing unit.

10. The memory device of claim 1, wherein the first computing unit generates the first partial sum by multiplying an input activation vector element with the stored weights within a sub-array of memory cells.

12. The memory device of claim 1, wherein the second computing unit generates the second partial sum by multiplying an input activation vector element with the stored weights within a sub-array of memory cells.

13. The memory device of claim 1, wherein each of the plurality of memory cells includes a plurality of word lines, and wherein multiplication of an input activation vector element with a weight stored in the plurality of memory cells is computed through access to a sub-array of memory cells via the plurality of word lines.

14. A memory device, comprising:
a substrate;
an array of memory cells having a plurality of sub-arrays of memory cells formed on the substrate and configured to store weights for a neural network;
a first local accumulator formed on a first metal layer and configured to receive the stored weights from the sub-arrays of memory cells, and to generate a first partial sum according to the stored weights;
a second local accumulator formed on the first metal layer and configured to receive the stored weights from the sub-arrays of memory cells and the first partial sum, and to generate a second partial sum according to the stored weights and the first partial sum, wherein the second local accumulator is sequentially coupled to the first local accumulator on the first metal layer.

15. The memory device of claim 14, comprising:
a third local accumulator formed on the first metal layer and configured to receive the stored weights from the sub-arrays of memory cells and the second partial sum, and to generate a third partial sum according to the stored weights and the second partial sum, wherein the third local accumulator is sequentially coupled to the first local accumulator and the second local accumulator on the first metal layer.

16. The memory device of claim 14, comprising:
a fourth local accumulator formed on a second metal layer and configured to receive the stored weights from the sub-arrays of memory cells and generate a fourth partial sum according to the stored weights;
a fifth computing unit formed on a second metal layer and configured to receive the stored weights from the sub-arrays of memory cells and generate a fifth partial sum according to the stored weights, wherein the first local accumulator is parallelly coupled to the fourth local accumulator and the fifth local accumulator to receive the fourth partial sum and the fifth partial sum, and to generate the first partial sum.

17. The memory device of claim 16, wherein the fourth local accumulator and the first local accumulator are in different metal layer, and the fourth local accumulator and the fifth local accumulator are in a same metallization layer.

18. The memory device of claim 17, wherein the fourth local accumulator is interconnected to the first local accumulator via a via structure, wherein the fifth local accumulator is interconnected to the first local accumulator via the via structure.

19. A method for fabricating a memory device, comprising:
providing a substrate;
forming an array of memory cells having a plurality of sub-arrays of memory cells on a frontside of the substrate;
forming a first local accumulator on a first metal layer on the frontside of the substrate; and
forming a second local accumulator on the first metal layer, wherein the first local accumulator is sequentially coupled to the second local accumulator on the first metal layer.

20. The method of claim 19, comprising:
forming a third local accumulator formed on the first metal layer, wherein the third local accumulator is sequentially coupled to the first local accumulator and the second local accumulator on the first metal layer.
